(19) United States
(12) Patent Application Publication
(10) Pub. No.: US 2026/0371910 A1
(43) Pub. Date: Nov. 19, 2026

(54) Display Device, Method Of Manufacturing The Same, And Electronic Device

(71) Applicant: Samsung Display Co., Ltd., Yongin-si (KR)

(72) Inventors: SUK WON JUNG, Yongin-si (KR); SANG-CHUL BYUN, Yongin-si (KR); Jaehyun Kim, Yongin-si (KR); JUNEHYOUNG PARK, Yongin-si (KR); HO YUN BYUN, Yongin-si (KR); HUI YEON SHON, Yongin-si (KR); HYUN JOON OH, Yongin-si (KR)

(73) Assignee: Samsung Display Co., Ltd., Yongin-si (KR)

(21) Appl. No.: 19/638,327

(22) Filed: Apr. 3, 2026

(30) Foreign Application Priority Data
May 19, 2025 (KR) 10-2025-0064461

(51) Int. Cl. H10K 59/80; H10K 59/12

(52) U.S. Cl. CPC H10K 59/8791; H10K 59/1201; H10K 59/873

(57) ABSTRACT

Provided is a display device including a display panel including a display area and a peripheral area surrounding the display area, a protective film layer arranged on the display panel, an adhesive layer arranged between the protective film layer and the display panel, and an anti-reflection layer arranged on the protective film layer, wherein the display panel includes a substrate, a pixel layer on the substrate, and a color filter layer on the pixel layer, and a storage modulus of the adhesive layer is less than a storage modulus of the protective film layer.

### CROSS-REFERENCE TO RELATED APPLICATION

This application is based on and claims priority under 35 USC §119 to Korean Patent Application No. 10-2025-0064461, filed on May 19, 2025, in the Korean Intellectual Property Office, the disclosure of which is incorporated herein by reference in its entirety.

### TECHNICAL FIELD

One or more aspects relate to a display device, a method of manufacturing the same, and an electronic device.

### BACKGROUND

As demand for display devices expands, the need for display devices which may be used for a variety of purposes is also increasing. In line with this trend, display devices are gradually larger and thinner, and the need for display devices which are larger and thinner while having accurate and vivid colors is also increasing.

The above-described information disclosed in the background technology of the disclosure is only intended to improve understanding of the background of the disclosure and therefore may include information that does not constitute the prior art.

### SUMMARY

One or more aspects provide a display device with improved stability and optical characteristics, a method of manufacturing the same, and an electronic device.

However, the technical problems to be solved by the disclosure are not limited to the problems described above, and other problems not mentioned may be clearly understood by those skilled in the art from the following description of the disclosure.

According to one or more aspects, a display device includes a display panel including a display area and a peripheral area surrounding the display area, a protective film layer arranged on the display panel, an adhesive layer arranged between the protective film layer and the display panel, and an anti-reflection layer arranged on the protective film layer, wherein the display panel includes a substrate, a pixel layer on the substrate, and a color filter layer on the pixel layer, and a storage modulus of the adhesive layer is less than a storage modulus of the protective film layer.

In an aspect, the protective film layer may include at least a urethane-based material.

In an aspect, a thickness of the protective film layer may be 100 μm to 300 μm.

In an aspect, an upper surface of the anti-reflection layer may include a moth-eye shape including a plurality of cone structures spaced apart from one another.

In an aspect, a distance between adjacent cone structures of the plurality of cone structures may be 0.25 μm to 0.35 μm.

In an aspect, a height of each of the plurality of cone structures may be 0.2 μm to 0.25 μm.

In an aspect, the anti-reflection layer may be arranged on an outermost layer, and a polarizing layer may not be arranged on the anti-reflection layer.

In an aspect, the anti-reflection layer may be arranged on an outermost layer, and a window may not be arranged on the anti-reflection layer.

According to one or more aspects, a method of manufacturing a display device includes forming a display panel, forming an adhesive layer on the display panel, forming a protective film layer on the adhesive layer, and forming an anti-reflection layer on the protective film layer, wherein forming the display panel includes forming a substrate, forming a pixel layer on the substrate, and forming a color filter layer on the pixel layer, and a storage modulus of the adhesive layer is less than a storage modulus of the protective film layer.

In an aspect, forming the adhesive layer may include applying an adhesive, which is a material of the adhesive layer, and curing the adhesive.

In an aspect, forming the protective film layer may include applying a protective resin, which is a material of the protective film layer, onto the adhesive layer, and curing the protective resin.

In an aspect, a thickness of the protective film layer may be 100 μm to 300 μm.

In an aspect, forming the anti-reflection layer may include applying an anti-reflection resin, which is a material of the anti-reflection layer, onto the protective film layer, and curing the anti-reflection resin.

In an aspect, between applying the anti-reflection resin and curing the anti-reflection resin, the anti-reflection resin may be printed to form a moth-eye shape including a plurality of cone structures spaced apart from one another.

In an aspect, a distance between adjacent cone structures of the plurality of cone structures may be 0.25 μm to 0.35 μm.

In an aspect, a height of each of the plurality of cone structures may be 0.2 μm to 0.25 μm.

In an aspect, the anti-reflection layer may be arranged on an outermost layer, and a polarizing layer may not be formed on the anti-reflection layer.

In an aspect, the anti-reflection layer may be arranged on an outermost layer, and a window may not be formed on the anti-reflection layer.

According to one or more aspects, an electronic device includes a display device, wherein the display device includes a display panel including a display area and a peripheral area surrounding the display area, a protective film layer arranged on the display panel, an adhesive layer arranged between the protective film layer and the display panel, and an anti-reflection layer arranged on the protective film layer, wherein the display panel includes a substrate, a pixel layer on the substrate, and a color filter layer on the pixel layer, and a storage modulus of the adhesive layer is less than a storage modulus of the protective film layer.

In an aspect, the anti-reflection layer may be arranged on an outermost layer, and a polarizing layer and a window may not be arranged on the anti-reflection layer.

### BRIEF DESCRIPTION OF THE DRAWINGS

The following drawings attached to this specification illustrate preferred aspects of the disclosure and, together with the detailed description of the disclosure described below, serve to further understand the technical idea of the disclosure; therefore, the disclosure should not be interpreted as being limited to matters described in such drawings:

FIG. 1 is a schematic perspective view of a display device according to an aspect;

FIG. 2 is a schematic cross-sectional view of an example of a cross-section taken along line I-I' of FIG. 1;

FIG. 3 is a schematic plane view of a portion of the display device of FIG. 1;

FIG. 4 is a schematic diagram of an equivalent circuit of a pixel in the display device of FIG. 1;

FIG. 5 is a schematic cross-sectional view of an example of a cross-section of the pixel in FIG. 3;

FIG. 6 is a schematic cross-sectional view of an aspect of a cross-section taken along line II-II' of FIG. 1;

FIG. 7 is a schematic cross-sectional view of another aspect of a cross-section taken along line II-II' of FIG. 1;

FIGS. 8-15 are schematic views of operation flows of a method of manufacturing a display device according to an aspect;

FIG. 16 is a block diagram of an electronic device according to aspect; and

FIG. 17 is a variety of schematic views of an electronic device according to various aspects.

### DETAILED DESCRIPTION

As the disclosure allows for various changes and numerous aspects, certain aspects will be illustrated in the drawings and described in detail in the written description. Effects and features of the disclosure, and methods of achieving them will be clarified with reference to aspects described below in detail with reference to the drawings. The disclosure may, however, be embodied in many different forms and should not be construed as being limited to the aspects set forth herein.

In the following aspects, the terms "first" and "second" are not used in a restrictive sense and are used to distinguish one element from another.

The singular forms as used herein are intended to include the plural forms as well unless the context clearly indicates otherwise.

It will be further understood that the terms "include" and/or "comprise" used herein specify the presence of stated features or elements, but do not preclude the presence or addition of one or more other features or elements.

In the aspects disclosed below, in case that a part, such as a unit, area, or element, is said to be located on another part, it will include not only the case where the part is directly located on the other part, but also the case where other intervening units, areas, or elements are present.

In the following aspects, it will be understood that the terms "connection" or "coupling" do not necessarily mean "direct and/or fixed connection or coupling" of two members, unless the context clearly indicates otherwise, and this does not preclude the arrangement of other members between the two members.

Sizes of elements in the drawings may be exaggerated for convenience of explanation. For example, since sizes and thicknesses of components in the drawings are arbitrarily illustrated for convenience of explanation, the following aspects are not limited thereto.

The disclosure will now be described more fully with reference to the accompanying drawings, in which preferred aspects of the disclosure are shown. Like reference numerals in the drawings denote like elements, and thus their description will not be repeated.

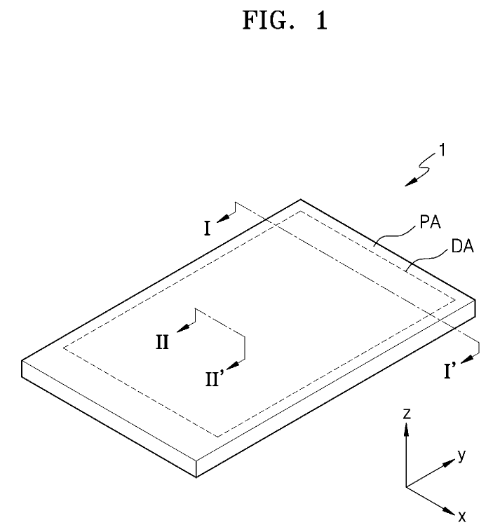

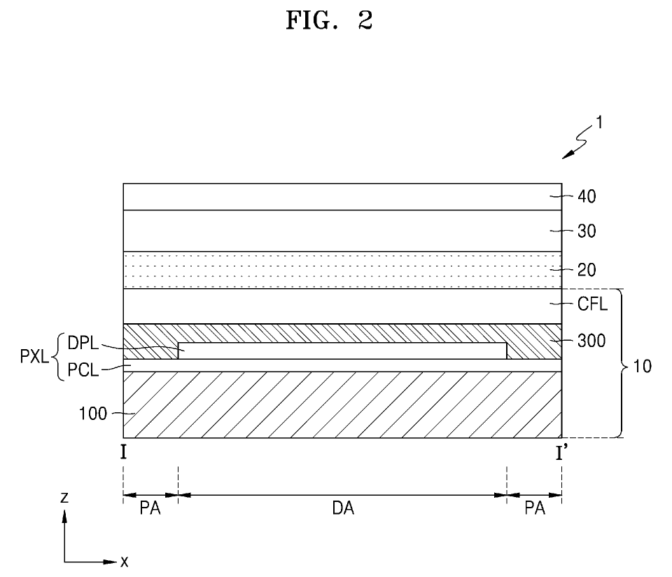

FIG. 1 is a schematic perspective view of a display device according to an aspect, and FIG. 2 is a schematic cross-sectional view of an example of a cross-section taken along line I-I' of FIG. 1.

Referring to FIG. 1, a display device 1 according to an aspect may include a display area DA and a peripheral area PA. The peripheral area PA may be arranged to surround the display area DA on the outside of the display area DA. The peripheral area PA may include various lines and driving circuits to transmit electrical signals to be applied to the display area DA. The display device 1 may provide a certain image by using light emitted from a plurality of pixels arranged in the display area DA. Although not shown, the display device 1 may be bent, by including a bending area, in a partial region of the peripheral area PA.

The display device 1 may be a display device, such as an organic light-emitting display device (OLED), an inorganic light-emitting display device (or inorganic EL display device), or a quantum dot light-emitting display device. Hereinafter, an organic light-emitting display device will be described as an example. The display device 1 may be implemented as various types of electronic devices, such as mobile phones, laptop computers, and smart watches.

As shown in FIG. 2, the display device 1 may include a display panel 10, a protective film layer 30 arranged on the display panel 10, and an anti-reflection layer 40 arranged on the protective film layer 30, which are sequentially stacked in a thickness direction (a z direction). For example, the display panel 10 may include a substrate 100, a pixel layer PXL on the substrate 100, an encapsulation member 300 arranged on the pixel layer PXL and encapsulating the pixel layer PXL, and a color filter layer CFL arranged on the encapsulation member 300, which are sequentially stacked in the thickness direction (the z direction). The display device 1 may include an adhesive layer 20 arranged between the color filter layer CFL and the protective film layer 30.

The substrate 100 may include a glass material or a polymer resin. For example, the substrate 100 may include a glass material containing SiO2 as a main component, or may include various materials having flexible or bendable properties, for example, a resin, such as a reinforced plastic. Although not shown, the substrate 100 may be bent, by including a bending area, in a partial region of the peripheral area PA.

The pixel layer PXL may be arranged on the substrate 100. The pixel layer PXL may include a display element layer DPL including display elements arranged for each pixel, and a pixel circuit layer PCL including pixel circuits and insulating layers arranged for each pixel. The display element layer DPL may be arranged on an upper layer of the pixel circuit layer PCL, and a plurality of insulating layers may be arranged between the pixel circuits and the display elements. Some of lines and insulating layers of the pixel circuit layer PCL may extend to the peripheral area PA.

The encapsulation member 300 may be a thin-film encapsulation layer. The thin-film encapsulation layer may include at least one inorganic encapsulation layer and at least one organic encapsulation layer. In case that the display device 1 includes the substrate 100 including a polymer resin, and the encapsulation member 300, which is the thin-film encapsulation layer including the inorganic encapsulation layer and the organic encapsulation layer, the flexibility of the display device 1 may be improved.

The color filter layer CFL may include color filters CF. In an optional aspect, the color filter layer CFL may include a black matrix BM. The color filter layer CFL may, in another optional aspect, achieve the same effect as the black matrix BM by replacing the black matrix BM with a combination of a first color filter, a second color filter, and a third color filter, which are different from one another.

Although not shown, other components may further be arranged on the color filter layer CFL. As an example, a cover member or the like may further be arranged on the color filter layer CFL.

The protective film layer 30 may protect the display device 1. For example, the protective film layer 30 may protect the display device 1 from external impact applied to the display device 1.

The adhesive layer 20 may be arranged between the display panel 10 and the protective film layer 30, for example, between the encapsulation member 300 and the protective film layer 30, so as to bond the encapsulation member 300 and the protective film layer 30.

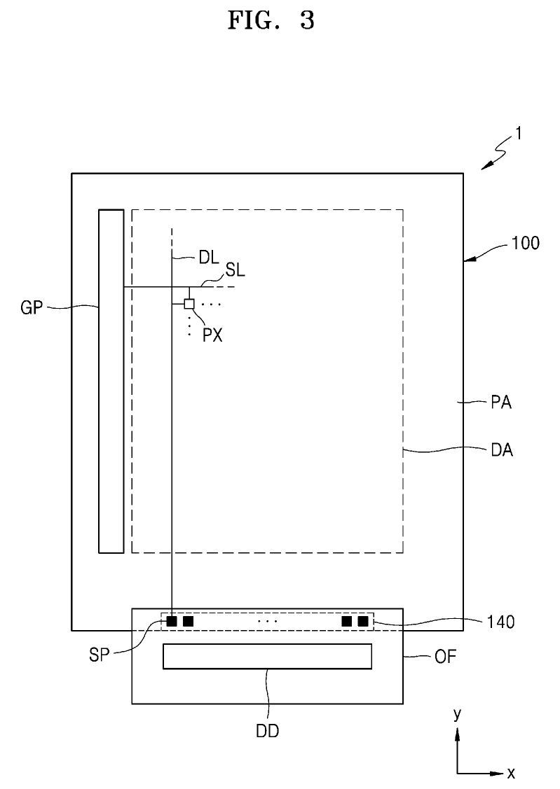

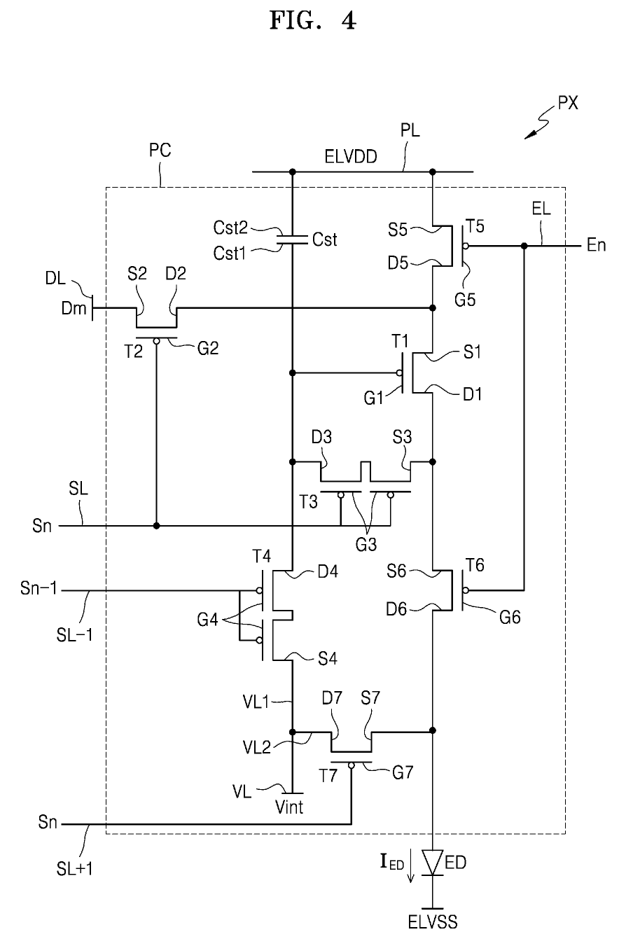

FIG. 3 is a schematic plane view of a portion of the display device of FIG. 1, and FIG. 4 is a schematic diagram of an equivalent circuit of a pixel in the display device of FIG. 1.

Referring to FIG. 3, the substrate 100 may include the display area DA and the peripheral area PA. The peripheral area PA may be located outside the display area DA and surround the display area DA.

The display area DA on the substrate 100 may include a plurality of pixels PX arranged in a certain pattern in a first direction (an x direction or a row direction) and a second direction (a y direction or a column direction).

The peripheral area PA on the substrate 100 may include a scan driver GP for applying a scan signal to each pixel PX, a data driver DD for applying a data signal to each pixel PX, and main power lines (not shown) for applying a first power voltage ELVDD (see FIG. 4) and a second power voltage ELVSS (see FIG. 4). A pad part 140 in which a plurality of signal pads SP connected to data lines DL are arranged may be located in the peripheral area PA on the substrate 100.

The scan driver GP may include an oxide semiconductor TFT gate driver circuit (OSG) or an amorphous silicon TFT gate driver circuit (ASG). In FIG. 3, the scan driver GP is shown as being arranged adjacent to one side of the substrate 100, but depending on the aspect, the scan driver GP may be arranged adjacent to each of two opposite sides of the substrate 100.

FIG. 3 shows a chip on film (COF) method in which the data driver DD is arranged on a film OF, which is electrically connected to signal pads SP arranged on the substrate 100. According to another aspect, the data driver DD may be arranged directly on the substrate 100 in a chip on glass (COG) or chip on plastic (COP) manner. The data driver DD may be electrically connected to a flexible printed circuit board (FPCB).

Referring to FIG. 4, a pixel PX may include a pixel circuit PC and an emission diode ED electrically connected to the pixel circuit PC.

Each pixel PX may emit, for example, red light, green light, blue light, or white light through the emission diode ED.

The pixel circuit PC, as shown in FIG. 4, may include a plurality of transistors T1 to T7 and a storage capacitor Cst. The transistors T1 to T7 and the storage capacitor Cst may be connected to signal lines SL, SL-1, SL+1, EL, and DL, a first initialization voltage line VL1, a second initialization voltage line VL2, and a driving voltage line PL.

The signal lines SL, SL-1, SL+1, EL, and DL may include a scan line SL transmitting a scan signal Sn, a previous scan line SL-1 transmitting a previous scan signal Sn-1 to a first initialization transistor T4, a subsequent scan line SL+1 transmitting the scan signal Sn to a second initialization transistor T7, an emission control line EL transmitting an emission control signal En to an operation control transistor T5 and an emission control transistor T6, and a data line DL crossing the scan line SL and transmitting a data signal Dm. The driving voltage line PL may transmit a driving voltage ELVDD to a driving transistor T1, the first initialization voltage line VL1 may transmit an initialization voltage Vint to the first initialization transistor T4, and the second initialization voltage line VL2 may transmit the initialization voltage Vint to the second initialization transistor T7.

A driving gate electrode G1 of the driving transistor T1 may be connected to a lower electrode CE1 of the storage capacitor Cst, a driving source electrode S1 of the driving transistor T1 may be connected to the lower driving voltage line PL via the operation control transistor T5, and a driving drain electrode D1 of the driving transistor T1 may be electrically connected to a pixel electrode of an emission diode ED via the emission control transistor T6. The driving transistor T1 may receive the data signal Dm according to a switching operation of a switching transistor T2 and supply a driving current I_{ed} to the emission diode ED.

A switching gate electrode G2 of the switching transistor T2 may be connected to the scan line SL, a switching source electrode S2 of the switching transistor T2 may be connected to the data line DL, and a switching drain electrode D2 of the switching transistor T2 may be connected to the driving source electrode S1 of the driving transistor T1 and to the lower driving voltage line PL via the operation control transistor T5. The switching transistor T2 may be turned on according to the scan signal Sn received through the scan line SL and perform a switching operation for transmitting the data signal Dm, which has been transmitted to the data line DL, to the driving source electrode S1 of the driving transistor T1.

A compensation gate electrode G3 of a compensation transistor T3 may be connected to the scan line SL, a compensation source electrode S3 of the compensation transistor T3 may be connected to the driving drain electrode D1 of the driving transistor T1 and to the pixel electrode of the emission diode ED via the emission control transistor T6, and a compensation drain electrode D3 of the compensation transistor T3 may be connected to the lower electrode CE1 of the storage capacitor Cst, a first initialization drain electrode D4 of the first initialization transistor T4, and the driving gate electrode G1 of the driving transistor T1. The compensation transistor T3 may be turned on according to the scan signal Sn received through the scan line SL, and may electrically connect the driving gate electrode G1 and the driving drain electrode D1 of the driving transistor T1 to diode-connect the driving transistor T1.

A first initialization gate electrode G4 of the first initialization transistor T4 may be connected to the previous scan line SL-1, a first initialization source electrode S4 of the first initialization transistor T4 may be connected to the first initialization voltage line VL1, and the first initialization drain electrode D4 of the first initialization transistor T4 may be connected to the lower electrode CE1 of the storage capacitor Cst, the compensation drain electrode D3 of the compensation transistor T3, and the driving gate electrode G1 of the driving transistor T1. The first initialization transistor T4 may be turned on according to the previous scan signal Sn-1 received through the previous scan line SL-1 and may transmit the initialization voltage Vint to the driving gate electrode G1 of the driving transistor T1, so as to perform an initialization operation for initializing a voltage of the driving gate electrode G1 of the driving transistor T1.

An operation control gate electrode G5 of the operation control transistor T5 may be connected to the emission control line EL, an operation control source electrode S5 of the operation control transistor T5 may be connected to the lower driving voltage line PL, and an operation control drain electrode D5 of the operation control transistor T5 may be connected to the driving source electrode S1 of the driving transistor T1 and the switching drain electrode D2 of the switching transistor T2.

An emission control gate electrode G6 of the emission control transistor T6 may be connected to the emission control line EL, an emission control source electrode S6 of the emission control transistor T6 may be connected to the driving drain electrode D1 of the driving transistor T1 and the compensation source electrode S3 of the compensation transistor T3, and an emission control drain electrode D6 of the emission control transistor T6 may be electrically connected to a second initialization source electrode S7 of the second initialization transistor T7 and the pixel electrode of the emission diode ED.

The operation control transistor T5 and the emission control transistor T6 may be simultaneously turned on according to the emission control signal En received through the emission control line EL, so that the driving voltage ELVDD is transmitted to the emission diode ED and the driving current I_{ed} flows in the emission diode ED.

A second initialization gate electrode G7 of the second initialization transistor T7 may be connected to the subsequent scan line SL+1, the second initialization source electrode S7 of the second initialization transistor T7 may be connected to the emission control drain electrode D6 of the emission control transistor T6 and the pixel electrode of the emission diode ED, and a second initialization drain electrode D7 of the second initialization transistor T7 may be connected to the second initialization voltage line VL2.

In some aspects, the scan line SL and the subsequent scan line SL+1 may be electrically connected to each other, and thus the same scan signal Sn may be applied to the scan line SL and the subsequent scan line SL+1. Accordingly, the second initialization transistor T7 may be turned on according to the scan signal Sn received through the subsequent scan line SL+1 to perform an operation of initializing the pixel electrode of the emission diode ED.

An upper electrode CE2 of the storage capacitor Cst may be connected to the driving voltage line PL, and a common electrode of the emission diode ED may be connected to a common voltage ELVSS. Accordingly, the emission diode ED may emit light by receiving the driving current I_{ed} from the driving transistor T1, so that an image is displayed.

In FIG. 4, the compensation transistor T3 and the first initialization transistor T4 are shown as having dual gate electrodes, but the compensation transistor T3 and the first initialization transistor T4 may have a single gate electrode.

Although FIG. 4 describes a structure for one pixel circuit PC, a plurality of pixels PX each having the same pixel circuit PC may be arranged to form a plurality of rows, and at this time, the first initialization voltage line VL1, the previous scan line SL-1, the second initialization voltage line VL2, and the subsequent scan line SL+1 may be shared by neighboring pixels PX.

For example, the first initialization voltage line VL1 and the previous scan line SL-1 may be electrically connected to a second initialization transistor of another pixel circuit PC which is arranged in the second direction (the y direction). Accordingly, the previous scan signal applied to the previous scan line SL-1 may be transmitted, as a subsequent scan signal, to the second initialization transistor of the other pixel circuit PC. Similarly, the second initialization voltage line VL2 and the subsequent scan line SL+1 may be electrically connected to a first initialization transistor of still another pixel circuit PC, which is arranged adjacently in the second direction y based on the drawing, to transmit the previous scan signal Sn-1 and the initialization voltage Vint.

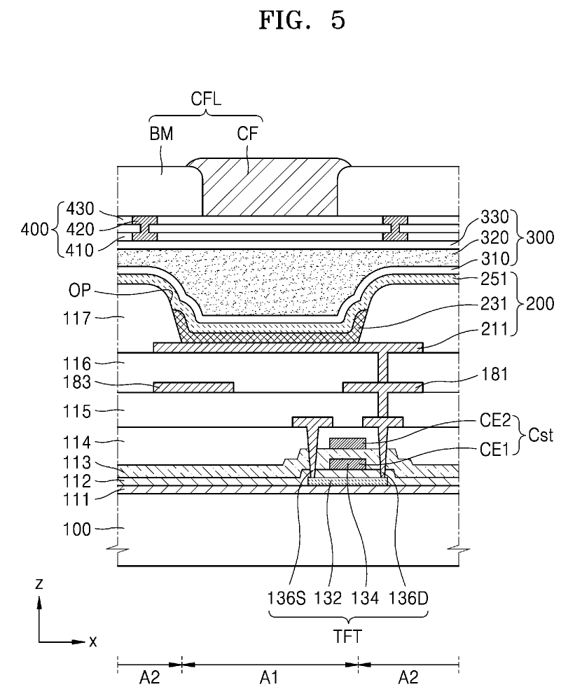

FIG. 5 is a schematic cross-sectional view of an example of a cross-section of the pixel in FIG. 3.

Referring to FIG. 5, a buffer layer 111 may be arranged on the substrate 100 to suppress impurities from penetrating a semiconductor layer of a thin-film transistor.

The substrate 100 may include various materials, such as glass, metal, or plastic. In an aspect, the substrate 100 may be a flexible substrate, and may include, for example, polymer resin, such as polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP).

The buffer layer 111 may include an inorganic insulating material, such as silicon nitride or silicon oxynitride, and may be a single layer or a multi-layer.

A thin-film transistor TFT, a capacitor Cst, and an emission element 200 electrically connected to the thin-film transistor TFT may be arranged on the substrate 100. The fact that the emission element 200 is electrically connected to the thin-film transistor TFT may be understood as meaning that a pixel electrode 211 is electrically connected to the thin-film transistor TFT. The thin-film transistor TFT may be the driving transistor T1 of FIG. 4.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include an amorphous silicon, a polycrystalline silicon, or an organic semiconductor material. The gate electrode 134 may include at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), taking into account adhesion to adjacent layers, surface flatness of stacked layers, and processability, and may be formed as a single layer or a multi-layer.

A gate insulating layer 112, which includes an inorganic material, such as silicon oxide, silicon nitride, and/or silicon oxynitride, may be arranged between the semiconductor layer 132 and the gate electrode 134. A first interlayer insulating layer 113 and a second interlayer insulating layer 114, each of which includes an inorganic material, such as silicon oxide, silicon nitride, and/or silicon oxynitride, may be arranged between the gate electrode 134 and the source electrode 136S and the drain electrode 136D. The source electrode 136S and the drain electrode 136D may be electrically connected to the semiconductor layer 132 through contact holes formed through the gate insulating layer 112, the first interlayer insulating layer 113, and the second interlayer insulating layer 114.

The source electrode 136S and the drain electrode 136D may include at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), and may be formed as a single layer or a multi-layer.

The capacitor Cst may include a lower electrode CE1 and an upper electrode CE2 which overlap each other with the first interlayer insulating layer 113 between the lower electrode CE1 and the upper electrode CE2. The capacitor Cst may overlap the thin-film transistor TFT. In FIG. 5, the gate electrode 134 of the thin-film transistor TFT is shown as the lower electrode CE1 of the capacitor Cst. As another aspect, the capacitor Cst may not overlap the thin-film transistor TFT. The capacitor Cst may be covered by the second interlayer insulating layer 114.

A pixel circuit including the thin-film transistor TFT and the capacitor Cst may be covered by a first insulating layer 115 and a second insulating layer 116. The first insulating layer 115 and the second insulating layer 116 may be organic insulating layers which are planarization insulating layers. The first insulating layer 115 and the second insulating layer 116 may each include an organic insulating layer, for example, a general-purpose polymer, such as polymethylmethacrylate (PMMA) or polystyrene (PS), a polymer derivative having a phenol group, an acrylic polymer, an imide polymer, an aryl ether polymer, an amide-based polymer, a fluorinated polymer, a p-xylene polymer, a vinyl alcohol polymer, and a blend thereof. In an aspect, the first insulating layer 115 and the second insulating layer 116 may include polyimide.

A display element, for example, an emission element 200, may be arranged on the second insulating layer 116. The emission element 200 may include a pixel electrode 211, an intermediate layer 231, and a counter electrode 251.

The pixel electrode 211 may be arranged on the second insulating layer 116, and may be connected to the thin-film transistor TFT through a connection electrode 181 on the first insulating layer 115. Lines 183, such as a data line DL and a driving voltage line PL, may be arranged on the first insulating layer 115.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). As another aspect, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another aspect, the pixel electrode 211 may further include a film which includes ITO, IZO, ZnO, or In₂O₃ and is located above/below the reflective film.

A third insulating layer 117 may be arranged on the second insulating layer 116. The third insulating layer 117 may cover an edge of the pixel electrode 211, and may be a pixel defining layer defining a pixel by having an opening OP, through which a portion of the pixel electrode 211 is exposed. The opening OP may correspond to a first area A1. The third insulating layer 117 may increase a distance between an edge of the pixel electrode 211 and the counter electrode 251, thereby suppressing a generation of arcs on the edge of the pixel electrode 211. The third insulating layer 117 may include an organic material, such as polyimide (PI) or hexamethyldisiloxane (HMDSO).

The intermediate layer 231 may include an emission layer. The emission layer may include a high-molecular or low-molecular organic material which emits light of a certain color. In an aspect, the intermediate layer 231 may include a first functional layer arranged below the emission layer and/or a second functional layer arranged above the emission layer. The first functional layer and/or the second functional layer may include a layer which is integrally formed over a plurality of pixel electrodes 211, or a layer which is patterned to correspond to each of the plurality of pixel electrodes 211.

The first functional layer may be a single layer or a multi-layer. For example, in case that the first functional layer includes a high-molecular material, the first functional layer may be a hole transport layer HTL with a single-layer structure, and may include poly-(3,4)-ethylene-dihydroxy thiophene (PEDOT) or polyaniline (PANI). In case that the first functional layer includes a low-molecular material, the first functional layer may include a hole injection layer HIL and a hole transport layer HTL.

The second functional layer may not always be arranged. For example, in case that each of the first functional layer and the emission layer includes a high-molecular material, it may be desirable to form the second functional layer to improve the characteristics of the emission diode. The second functional layer may be a single layer or a multi-layer. The second functional layer may include an electron transport layer ETL and/or an electron injection layer EIL.

The counter electrode 251 may be arranged to oppose the pixel electrode 211 with the intermediate layer 231 between the counter electrode 251 and the intermediate layer 231. The counter electrode 251 may include a conductive material having a relatively low work function. For example, the counter electrode 251 may include a (semi)transparent layer which includes silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another example, the counter electrode 251 may further include a layer, such as ITO, IZO, ZnO or In₂O₃, on the (semi)transparent layer including the aforementioned material.

The counter electrode 251 may be arranged on the intermediate layer 231 and the third insulating layer 117. The counter electrode 251 may be formed integrally over a plurality of emission elements 200 in the display area DA, and may oppose the plurality of pixel electrodes 211.

A thin-film encapsulation layer may be arranged as an encapsulation member 300 on the counter electrode 251. The thin-film encapsulation layer may serve to protect the emission element 200 from external moisture or oxygen. The thin-film encapsulation layer may have a multi-layer structure. The thin-film encapsulation layer may include a first inorganic layer 310, an organic layer 320, and a second inorganic layer 330. By forming the thin-film encapsulation layer of the multi-layer structure, even in case that cracks are generated on the thin-film encapsulation layer, the connection of the cracks may be suppressed between the first inorganic layer 310 and the organic layer 320 or between the organic layer 320 and the second inorganic layer 330. This may suppress or minimize the formation of a path through which external moisture or oxygen penetrates the display area DA. In another aspect, the number of organic layers 320, the number of inorganic layers, and a stacking order of the organic layer and the inorganic layers may vary.

The first inorganic layer 310 may cover the counter electrode 251, and may include at least one inorganic insulating material, such as aluminum oxide, titanium oxide, tantalum oxide, hafnium oxide, zinc oxide, silicon oxide, silicon nitride, or silicon oxynitride. The first inorganic layer 310 may be formed along a structure below the first inorganic layer 310, and thus an upper surface of the first inorganic layer 310 may not be flat.

The organic layer 320 may cover the first inorganic layer 310 and may have a sufficient thickness. An upper surface of the organic layer 320 may be substantially flat in the entire display area DA. The organic layer 320 may include polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, and polyacrylic acid), or any combination thereof.

The second inorganic layer 330 may cover the organic layer 320, and may include at least one inorganic insulating material, such as aluminum oxide, titanium oxide, tantalum oxide, hafnium oxide, zinc oxide, silicon oxide, silicon nitride, or silicon oxynitride. The second inorganic layer 330 may extend to the outside of the organic layer 320 to be in contact with the first inorganic layer 310 in the peripheral area PA, thereby suppressing the organic layer 320 from being exposed to the outside.

In some aspects, during the process of forming the thin-film encapsulation layer, structures below the thin-film encapsulation layer may be damaged. For example, in case of forming the first inorganic layer 310, a layer formed directly below the first inorganic layer 310 may be damaged. Therefore, to suppress damage to the lower structure during the process of forming the thin-film encapsulation layer, at least one capping layer and/or protective layer may be arranged between the counter electrode 251 and the thin-film encapsulation layer. The protective layer may include an inorganic material.

As an optional aspect, a touch sensing layer 400 may be arranged on the encapsulation member 300. The touch sensing layer 400 may include a first insulating layer 410, a second insulating layer 420 formed on the first insulating layer 410, and a plurality of touch electrodes 430 formed between the first insulating layer 410 and the second insulating layer 420. The touch electrode 430 is not limited to the structure shown in FIG. 5, and may include various electrode structures, such as a mesh electrode pattern and a transparent segment electrode.

The touch sensing layer 400 may sense a touch input based on a change in mutual capacitance, which is caused by a touch input. For example, in case that a touch input is applied, the mutual capacitance may change due to the touch input, and a touch sensing unit (not shown), which is connected to the touch sensing layer 400, may sense the touch input by detecting a position where the mutual capacitance has changed. However, this aspect is not limited to a specific touch sensing method.

A color filter layer CFL may be arranged on the encapsulation member 300. In case that the touch sensing layer 400 is arranged on the encapsulation member 300, the color filter layer CFL may be arranged on the touch sensing layer 400.

The color filter layer CFL may include a plurality of color filters CF which filter light generated from the emission diodes ED and transmit the filtered light to the outside, and each color filter CF may be arranged to correspond to an opening OP which defines the emission area of the corresponding emission diode ED.

The color filters CF of the color filter layer CFL and the black matrix BM may perform a function of suppressing external light reflection.

The color filters CF may filter a plurality of colors each corresponding to the emission area of the corresponding pixel PX. For example, in case that a first pixel emits red light, a first color filter may filter the red light, in case that a second pixel emits green light, a second color filter may filter the green light, and in case that a third pixel emits blue light, a third color filter may filter the blue light.

In this case, the first color filter, which is a red color filter, may include a red pigment or dye, the second color filter, which is a green color filter, may include a green pigment or dye, and the third color filter, which is a blue color filter, may include a blue pigment or dye. The red pigment, green pigment, and blue pigment may be any known pigments commonly used in forming color filters. For example, C.I pigment red series may be used as the red pigment, C.I pigment green series may be used as the green pigment, and a phthalocyanine pigment or an indanthrone blue pigment may be used as the blue pigment.

As an optional aspect, the color filter layer CFL may include a black matrix BM. The black matrix BM may include an opening in an area corresponding to the emission area in the z direction, and the color filter CF may be arranged in the opening.

The black matrix BM may include a material which is capable of shielding light. As an example, the black matrix BM may include at least one of a metal or opaque organic film material, such as chromium oxide (CrOx), carbon black, carbon nanotube, or a black dye. The black matrix BM may include a coloring agent, such as a pigment or dye. The black matrix BM may have a single-layer or multi-layer structure.

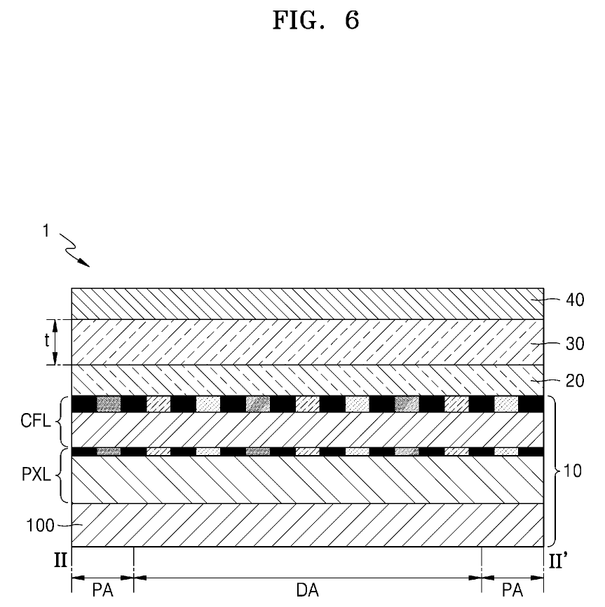

FIG. 6 is a schematic cross-sectional view of an aspect of a cross-section taken along line I-I' of FIG. 1.

Referring to FIG. 6, the display device 1 may include a display panel 10 including a display area DA and a peripheral area PA surrounding the display area DA, a protective film layer 30 arranged on the display panel 10, and an anti-reflection layer 40 arranged on the protective film layer 30.

The display panel 10 may include the display area DA and the peripheral area PA. At this time, pixels may be arranged in the display area DA. The display panel 10 may provide an image using light emitted from the pixels. Each pixel PX may emit light using a display element. In an aspect, the display element may be an emission diode ED. As an example, each pixel PX may emit red light, green light, or blue light. As another example, each pixel PX may emit red light, green light, blue light, or white light.

In an aspect, the display panel 10 may include at least one of the substrate 100, the pixel layer PXL on the substrate 100, and the color filter layer CFL on the pixel layer PXL, which have been described with reference to FIGS. 1-5. As a specific aspect, the display panel 10 may include all of the substrate 100, the pixel layer PXL on the substrate 100, and the color filter layer CFL on the pixel layer PXL, which have been described with reference to FIGS. 1-5. However, the disclosure is not limited thereto, and the display panel 10 may further include additional components which perform other functions.

In some aspects, a polarizing layer may be a layer which performs a function of selectively transmitting light emitted from the display element of the display element layer DPL. In some aspects, the polarizing layer may be a layer which transmits only light oscillating in the same direction as a polarization axis, among light emitted from the display element of the display element layer DPL, and absorbs or reflects light oscillating in other directions. By applying the color filter layer CFL, instead of the polarizing layer, to the display device 1, emission efficiency and color gamut of the display device 1 may be improved.

The display device 1 may not include a window (or cover glass, hereinafter, commonly referred to as a window) or cover glass. In some aspects, the display device 1 according to the aspect may be expressed as a film-type protective film layer 30 functionally replacing a window including a glass material. Accordingly, the display device 1 according to the aspect may have various superior effects compared to a case where the window including the glass material is arranged. For example, the display device 1 according to the aspect may be entirely reduced in thickness or weight.

For example, the display device 1 may not include a window, and thus may employ the protective film layer 30 which may perform an impact-resistant function.

The protective film layer 30 may be arranged on the display panel 10. The protective film layer 30 may perform a function of protecting the display device 1 from external impact.

In an aspect, the protective film layer 30 may include a protective film. The protective film may include various materials having high impact-resistance and flexible or bendable characteristics. For example, the protective film may include a resin, such as plastic. In another aspect, the protective film layer 30 may include an organic material.

In an aspect, the protective film layer 30 may include at least a urethane-based material. As an example, the protective film may be a urethane acrylate film including urethane acrylate.

The protective film layer 30 may have a thickness t which is sufficient to protect the display device 1 from external impact even without a window, while minimizing the thickness and weight of the display device 1. As an example, the thickness t of the protective film layer 30 may be 100 μm to 300 μm. For example, the thickness t of the protective film layer 30 may be 100 μm to 200 μm.

An adhesive layer 20 may be arranged between the display panel 10 and the protective film layer 30 to perform a function of adhering the display panel 10 and the protective film layer 30 to each other.

The adhesive layer 20 may include an adhesive film. As an example, the adhesive film may include a resin, such as acrylic, polyimide, or polycarbonate which has light-transmitting properties.

The adhesive layer 20 may also improve the impact resistance of the display device 1 which does not include a window.

Storage modulus is a type of elastic modulus, which may be elastic energy stored in case that a material is deformed by external force. The storage modulus may be a value which indicates how effectively a material may store external force and release the external force later.

The storage modulus of the adhesive layer 20 may be smaller than the storage modulus of the protective film layer 30. Compared to a display device which includes only the protective film layer 30 without the adhesive layer 20, the display device 1 in which the adhesive layer 20 having the lower storage modulus is further arranged below the protective film layer 30 may be more resistant to external impact.

The protective film layer 30 with the high storage modulus may perform a function of dispersing external impact, and the adhesive layer 20 with the low storage modulus may perform a function of absorbing external impact. For example, in case that the adhesive layer 20 having the low storage modulus is arranged below the protective film layer 30 having the high storage modulus, an anti-impact function of the display device 1 may be improved by strain-decoupling.

As an example, the storage modulus of the adhesive layer 20 may be less than or equal to 0.5 MPa at 25° C. When the storage modulus of the adhesive layer 20 is greater than 0.5 MPa at 25° C, the external impact absorption capacity may be reduced.

As an example, the storage modulus of the protective film layer 30 may be at least 2 GPa at -20° C. When the storage modulus of the protective film layer 30 is less than 2 GPa at -20° C, an external impact dispersion capacity may be reduced.

Young's modulus is a physical property which represents the elasticity of a material, and is an indicator of how well a material responds to and is deformed due to external stress. A high Young's modulus may indicate that a material is hard and rigid and exhibits less deformation in response to external stress, while a low Young's modulus may indicate that a material exhibits relatively great deformation in response to external stress and has more flexible characteristics. As an example, the Young's modulus of the protective film layer 30 may be greater than 0.7 GPa at 25° C.

The thickness of the adhesive layer 20 may be, for example, 50 μm or less.

When a polarizing layer is arranged on the protective film layer 30 without a window, for example, the outermost layer of the display device 1 is the polarizing layer. In that case there may be a problem in that the polarizing layer shrinks while the display device 1 is continuously used and time elapses. In this case, due to the shrinkage of the polarizing layer, the protective film layer 30 and the display panel 10 below the polarizing layer may also be subjected to a curling problem. For example, a problem that the entire display device 1 curls may occur.

To solve the problem of shrinkage of the display device 1 due to the polarizing layer being arranged on the uppermost layer of the display device 1 without a window, the polarizing layer may not be used. For example, the display device 1 may not include a window nor a polarizing layer.

However, the polarizing layer may function to reduce external light reflection, and there may be a problem in that the reduction of the external light reflection only by the color filter CF of the color filter layer CFL and the black matrix BM is less than that by the polarizing layer. To address this problem, the anti-reflection layer 40 may be applied to the display device 1.

The anti-reflection layer 40 may be arranged on the protective film layer 30. The anti-reflection layer 40 may reduce the reflectance of light (external light) which is incident from the outside toward the display device 1.

When the anti-reflection layer 40 is arranged as the outermost layer of the display device 1, for example, when the anti-reflection layer 40 is arranged on the uppermost layer of the display device 1 without an upper layer, such as a window or cover glass, on the anti-reflection layer 40, the anti-reflection layer 40 may include a material with high hardness.

An upper substrate including glass may not be included on the anti-reflection layer 40 of the display device 1. For example, an upper substrate including at least glass may not be arranged on the anti-reflection layer 40. The upper substrate may refer to a layer including glass. However, the upper substrate is not limited to the layer including at least the glass, and may be a layer identical or similar to the substrate 100.

A polarizing layer may not be arranged on the anti-reflection layer 40, and thus, the display device 1 may not curl. The thickness and weight of the display device 1 may be reduced by virtue of the exclusion of the polarizing layer on the display device 1.

The high-hardened anti-reflection layer 40 may further include a hard coating layer on the uppermost portion of the anti-reflection layer 40, as an optional aspect, to protect the anti-reflection layer 40 from external impact. For example, the hard coating layer may be arranged on the outermost side of the display device 1. The hard coating layer may have a function of suppressing scratches and may have a hardness of approximately 9 H.

The hard coating layer may include an organic material, such as a polymer resin. However, the disclosure is not limited thereto. The hard coating layer may also include an inorganic material.

The hard coating layer may be the outermost layer of the display device 1. This may be a layer which a user touches directly, and may provide smooth and soft touch feel to the user.

The anti-reflection layer 40 may include, for example, a phase retarder. The phase retarder may be of film type or liquid crystal coating type, and the film type phase retarder may include a stretchable synthetic resin film, and the liquid crystal coating type phase retarder may include liquid crystals arranged in a certain array.

Although not shown, the display device 1 may further include an optically transparent adhesive layer arranged on a lower surface of the anti-reflection layer 40. The optically transparent adhesive layer may attach the anti-reflection layer 40 to the protective film layer 30.

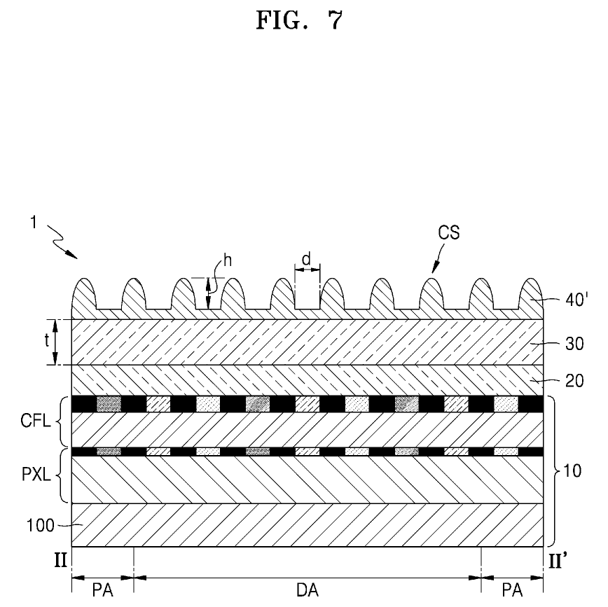

FIG. 7 is a schematic cross-sectional view of another aspect of a cross-section taken along line I-I' of FIG. 1.

Referring to FIG. 7, the display device 1 may include a display panel 10 including a display area DA and a peripheral area PA surrounding the display area DA, a protective film layer 30 arranged on the display panel 10, and an anti-reflection layer 40' arranged on the protective film layer 30.

In an aspect, the display panel 10 may include at least one of the substrate 100, the pixel layer PXL on the substrate 100, and the color filter layer CFL on the pixel layer PXL, which have been described with reference to FIGS. 1-5. As a specific aspect, the display panel 10 may include all of the substrate 100, the pixel layer PXL on the substrate 100, and the color filter layer CFL on the pixel layer PXL, which have been described with reference to FIGS. 1-5. However, the disclosure is not limited thereto, and the display panel 10 may further include additional components which perform other functions.

By applying the color filter layer CFL, instead of a polarizing layer, to the display device 1, emission efficiency and color gamut of the display device 1 may be improved.

The display device 1 may not include a window (or cover glass, hereinafter, commonly referred to as a window) or cover glass. In some aspects, the display device 1 according to the aspect may be expressed as a film-type protective film layer 30 functionally replacing a window including a glass material. Accordingly, the display device 1 according to the aspect may have various superior effects compared to a case where a window including a glass material is arranged. For example, the display device 1 according to the aspect may be entirely reduced in thickness or weight.

For example, the display device 1 may not include a window, and thus may employ the protective film layer 30 which may perform an impact-resistant function.

The protective film layer 30 may be arranged on the display panel 10. The protective film layer 30 may perform a function of protecting the display device 1 from external impact.

In an aspect, the protective film layer 30 may include a protective film. The protective film may include various materials having high impact-resistance and flexible or bendable characteristics. For example, the protective film may include a resin, such as plastic. In another aspect, the protective film layer 30 may include an organic material.

In an aspect, the protective film layer 30 may include at least a urethane-based material. As an example, the protective film may be a urethane acrylate film including urethane acrylate.

The protective film layer 30 may have a thickness t which is sufficient to protect the display device 1 from external impact even without a window, while minimizing the thickness and weight of the display device 1. As an example, the thickness t of the protective film layer 30 may be 100 μm to 300 μm. For example, the thickness t of the protective film layer 30 may be 100 μm to 200 μm.

An adhesive layer 20 may be arranged between the display panel 10 and the protective film layer 30 to perform a function of adhering the display panel 10 and the protective film layer 30 to each other.

The adhesive layer 20 may include an adhesive film. As an example, the adhesive film may include a resin, such as acrylic, polyimide, or polycarbonate which has light-transmitting properties.

The adhesive layer 20 may also improve the impact resistance of the display device 1 which does not include a window.

The storage modulus of the adhesive layer 20 may be smaller than the storage modulus of the protective film layer 30. Compared to a display device which includes only the protective film layer 30 without the adhesive layer 20, the display device 1 in which the adhesive layer 20 having the lower storage modulus is further arranged below the protective film layer 30 may be more resistant to external impact.

The protective film layer 30 with the high storage modulus may perform a function of dispersing external impact, and the adhesive layer 20 with the low storage modulus may perform a function of absorbing external impact. For example, in case that the adhesive layer 20 having the low storage modulus is arranged below the protective film layer 30 having the high storage modulus, an anti-impact function of the display device 1 may be improved by strain-decoupling.

As an example, the storage modulus of the adhesive layer 20 may be less than 0.5 MPa at 25° C, and the storage modulus of the protective film layer 30 may be at least 2 GPa at -20° C.

As an example, the Young's modulus of the protective film layer 30 may be greater than 0.7 GPa at 25° C.

The thickness of the adhesive layer 20 may be, for example, 50 μm or less.

When a polarizing layer is arranged on the protective film layer 30 without a window, for example, when the outermost layer of the display device 1 is the polarizing layer, there may be a problem that the polarizing layer shrinks while the display device 1 is continuously used and time elapses. In this case, due to the shrinkage of the polarizing layer, the protective film layer 30 and the display panel 10 below the polarizing layer may also be subjected to a curling problem. For example, a problem that the entire display device 1 curls may occur.

To solve the problem of shrinkage of the display device 1 due to the polarizing layer being arranged on the uppermost layer of the display device 1 without a window, the polarizing layer may not be used. For example, the display device 1 may not include a window nor a polarizing layer.

However, the polarizing layer may function to reduce external light reflection, and there may be a problem in that reduction of external light reflection only by the color filter CF of the color filter layer CFL and the black matrix BM is less than that by the polarizing layer. To solve this, the anti-reflection layer 40' may be applied to the display device 1.

The anti-reflection layer 40' may be arranged on the protective film layer 30. The anti-reflection layer 40' may reduce the reflectance of light (external light) which is incident from the outside toward the display device 1.

An upper surface of the anti-reflection layer 40' may include a moth-eye shape including a plurality of cone structures CS spaced apart from one another.

The moth-eye structure may be a structure which mimics a structure of a moth's eye, and may reduce surface reflection. For example, the moth-eye structure may be used as an anti-reflective coating layer. The moth-eye structure may reduce light reflection from a surface and minimize reflected light, thereby improving the visibility of a screen.

The moth-eye-shaped cone structure CS may be, for example, an irregular pattern at nanoscales and may induce light scattering in various directions on the screen. The moth-eye-shaped cone structure CS may suppress light from being completely reflected when the light reaches the surface, and instead may minimize the reflection by absorbing or re-emitting the light.

For example, by applying the anti-reflection layer 40' having an upper surface of the moth-eye shape to the display device 1, the visibility of the display device 1 may be improved and the screen may become clearer, thereby enhancing display quality.

A distance d between adjacent cone structures CS of the plurality of cone structures CS may be, for example, 0.25 μm to 0.35 μm. A height h of each of the plurality of cone structures CS may be, for example, 0.2 μm to 0.25 μm.

In case that the anti-reflection layer 40' is arranged as the outermost layer of the display device 1, for example, in case that the anti-reflection layer 40' is arranged on the uppermost layer of the display device 1 without an upper glass layer, such as a window or cover glass, on the anti-reflection layer 40', the anti-reflection layer 40' may include a material with high hardness.

The anti-reflection layer 40' may have high hardness to suppress scratches on the surface, and as an example, the anti-reflection layer 40' may include at least an epoxy-based material.

An upper substrate including glass may not be included on the anti-reflection layer 40' of the display device 1. For example, an upper substrate including at least glass may not be arranged on the anti-reflection layer 40'. The upper substrate may refer to a layer including glass. However, the upper substrate is not limited to the layer including at least the glass, and may be a layer identical or similar to the substrate 100.

A polarizing layer may not be arranged on the anti-reflection layer 40', and thus, the display device 1 may not curl. The thickness and weight of the display device 1 may be reduced by virtue of the exclusion of the polarizing layer on the display device 1.

The high-hardened anti-reflection layer 40' may further include a hard coating layer on the uppermost portion of the anti-reflection layer 40', as an optional aspect, to protect the anti-reflection layer 40' from external impact. For example, the hard coating layer may be arranged on the outermost side of the display device 1. The hard coating layer may have a function of suppressing scratches and may have a hardness of approximately 9 H.

The hard coating layer may include an organic material, such as a polymer resin. However, the disclosure is not limited thereto. The hard coating layer may also include an inorganic material.

The hard coating layer may be the outermost layer of the display device 1. This may be a layer which a user touches directly, and may provide smooth and soft touch feel to the user.

The anti-reflection layer 40' may include, for example, a phase retarder. The phase retarder may be of film type or liquid crystal coating type, and the film type phase retarder may include a stretchable synthetic resin film, and the liquid crystal coating type phase retarder may include liquid crystals arranged in a certain array.

Although not shown, the display device 1 may further include an optically transparent adhesive layer arranged on a lower surface of the anti-reflection layer 40'. The optically transparent adhesive layer may attach the anti-reflection layer 40' to the protective film layer 30.

In a range without contradicting the description in FIG. 7, the configuration of the display device 1 in FIG. 6 may be applied equally.

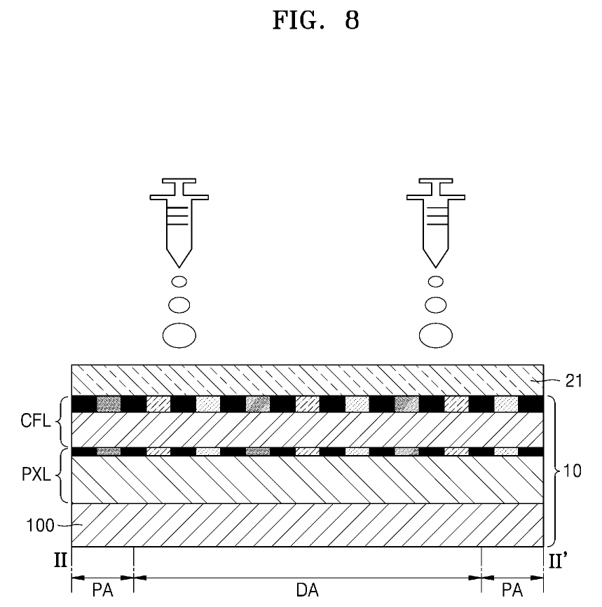

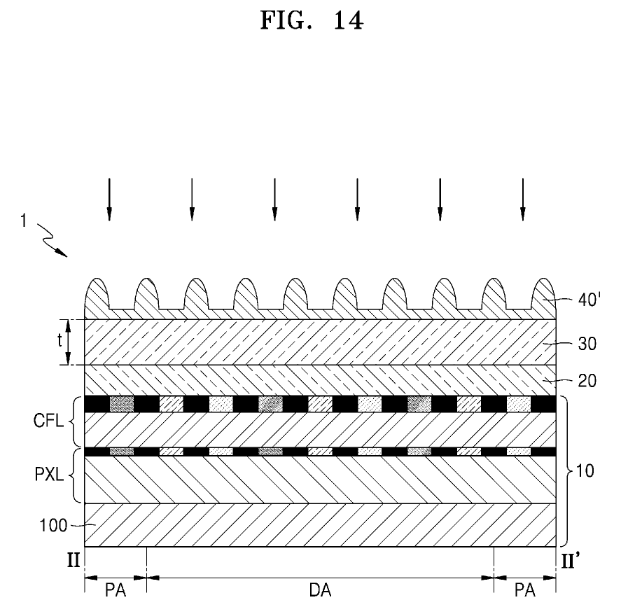

FIGS. 8-15 are schematic views of operation flows of a method of manufacturing a display device according to an aspect. For example, FIGS. 8-15 are schematic cross-sectional views of processes of manufacturing the display device 1 of FIG. 7.

Referring to FIGS. 8-15, a method of manufacturing a display device according to the disclosure may include forming a display panel 10, forming a protective film layer 30 on the display panel 10, and forming an anti-reflection layer 40' on the protective film layer 30.

Forming the display panel 10 may include forming a substrate 100, forming a pixel layer PXL on the substrate 100, and forming a color filter layer CFL on the pixel layer PXL.

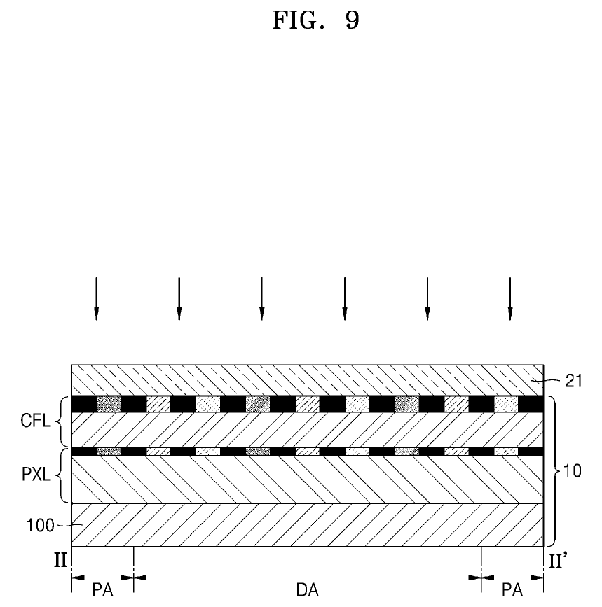

Referring to FIGS. 8 and 9, the manufacturing method may further include forming an adhesive layer 20 between forming the display panel 10 and forming the protective film layer 30.

Forming the adhesive layer 20 may include a step of applying an adhesive 21, which is a material of the adhesive layer 20, and a step of curing the adhesive 21. As an example, the adhesive 21 may be UV-cured. The adhesive layer 20 which is formed through these steps may have a thickness of, for example, 50 μm or less.

To manufacture the display device 1 which is more resistant to external impact than a display device including only the protective film layer 30 without the adhesive layer 20, the adhesive layer 20 may be formed so that the storage modulus of the adhesive layer 20 is smaller than the storage modulus of the protective film layer 30.

The adhesive layer 20 may have a low storage modulus to absorb the force of an external impact. As an example, the adhesive layer 20 may be formed to have a storage modulus of 0.5 MPa or less at 25° C.

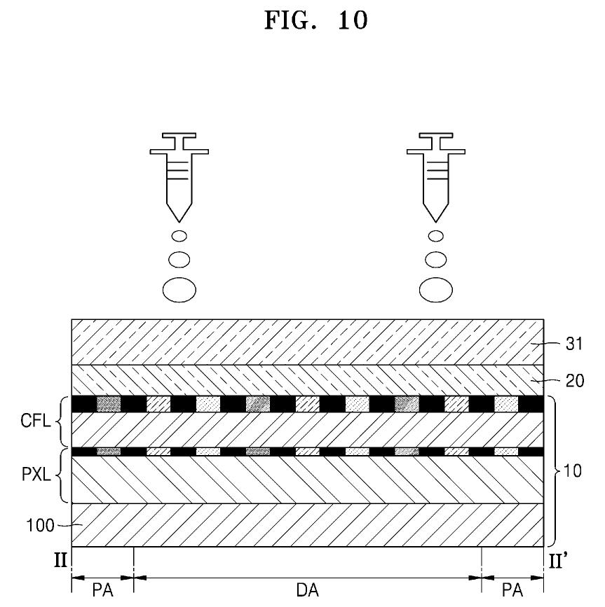

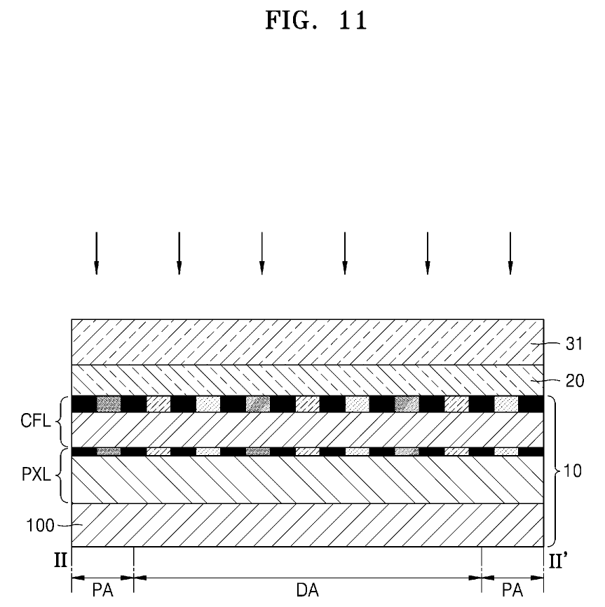

Referring to FIGS. 10 and 11, forming the protective film layer 30 after forming the adhesive layer 20 may include applying a protective resin 31, which is a material of the protective film layer 30, onto the adhesive layer 20, and curing the protective resin 31. As an example, the protective resin 31 may be UV-cured.

The protective film layer 30 may have a thickness t which is sufficient to protect the display device 1 from external impact even without a window, while minimizing the thickness and weight of the display device 1.

The thickness t of the protective film layer 30 may be, for example, 100 μm to 300 μm. For example, the thickness t of the protective film layer 30 may be 100 μm to 200 μm.

The protective film layer 30 may have a high storage modulus to disperse the force of an external impact. As an example, the protective film layer 30 may be formed to have a storage modulus of at least 2 GPa at -20° C.

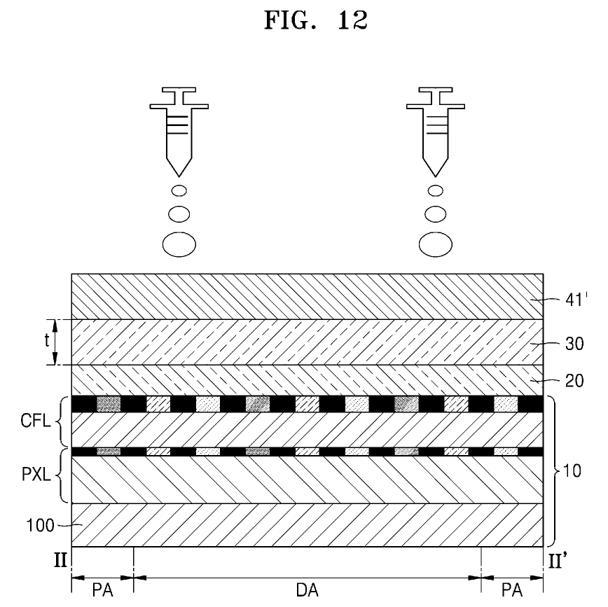

Referring to FIGS. 12-15, forming the anti-reflection layer 40' may include applying an anti-reflection resin 41', which is a material of the anti-reflection layer 40', onto the protective film layer 30 and curing the anti-reflection resin 41'. As an example, the anti-reflection resin 41' may be UV-cured.

Between applying the anti-reflection resin 41' and curing the anti-reflection resin 41', the anti-reflection resin 41' may be printed to form a moth-eye shape, which includes a plurality of cone structures CS spaced apart from one another. The anti-reflection layer 40' of FIG. 7 may be formed when the moth-eye shape is printed, while the anti-reflection layer 40 of FIG. 6 may be formed in case that the moth-eye shape is not printed.

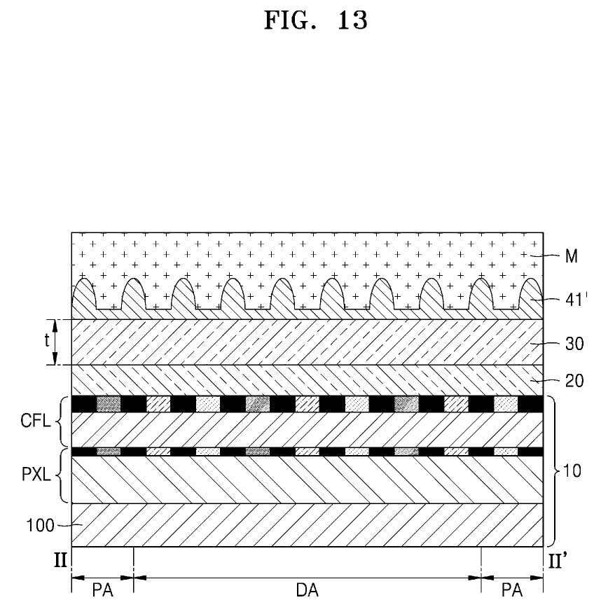

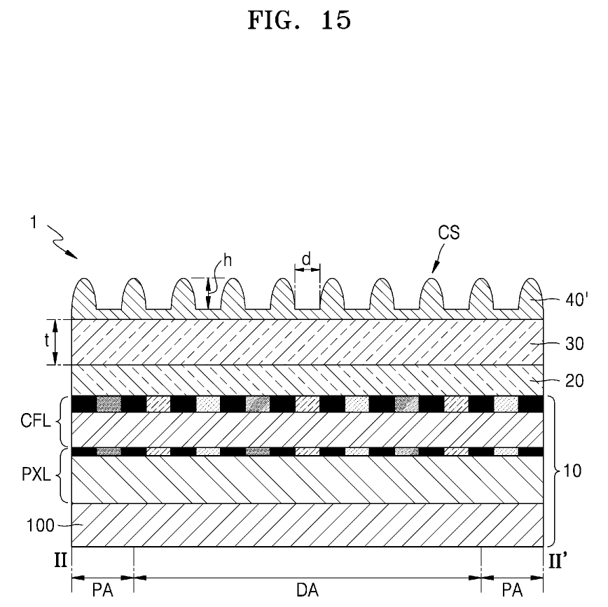

In some aspects, the moth-eye shape may be formed by pressing an upper surface of the applied anti-reflection resin 41' with a mold M (see FIG. 13). Referring to FIG. 15, a distance “d” between adjacent cone structures of the plurality of cone structures CS formed by pressing the anti-reflection resin 41' with the mold M may be, for example, 0.25 μm to 0.35 μm, and a height “h” of each of the plurality of cone structures CS may be, for example, 0.2 μm to 0.25 μm.

The anti-reflection layer 40' may be arranged on the outermost side of the display device 1. An upper substrate and a polarizing layer may not be formed on the anti-reflection layer 40'.

The display device 1 according to an aspect may be applied to various electronic devices 1000. An electronic device 1000 according to an aspect may include the display device 1 described above, and may further include a module or device having an additional function in addition to the display device 1.

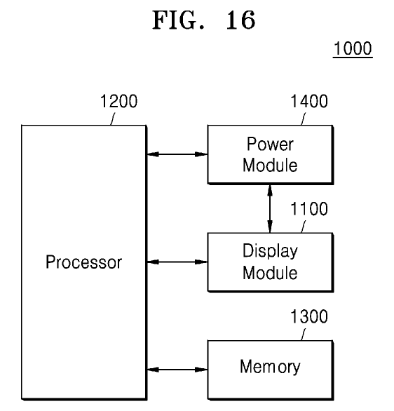

FIG. 16 is a block diagram of an electronic device according to aspect. Referring to FIG. 16, an electronic device 1000 according to an aspect may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), or a controller.

The memory 1300 may store data information which is required for the operation of the processor 1200 or the display module 1100. In case that the processor 1200 executes an application stored in the memory 1300, an image data signal and/or an input control signal may be transmitted to the display module 1100, and the display module 1100 may process the received signal and output image information through a display screen.

The power module 1400 may include a power supply module, such as a power adapter or a battery device, and a power conversion module which converts power supplied by the power supply module to generate power required for the operation of the electronic device 1000.

At least one of the components of the electronic device 1000 may be included in the display device 1 according to the foregoing aspects. Some of the individual modules functionally included in a single module may be included in the display device and others may be provided separately from the display device. For example, the display device 1 may include the display module 1100, and the processor 1200, the memory 1300, and the power module 1400 may be provided as other devices inside the electronic device 1000 other than the display device 1.

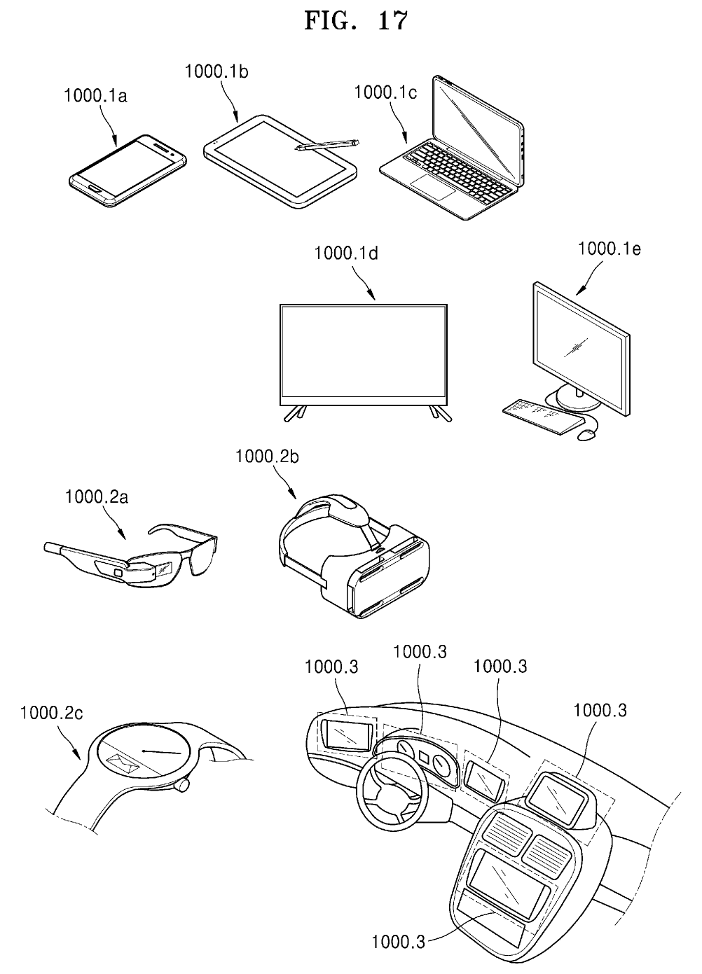

FIG. 17 is a variety of schematic views of an electronic device according to various aspects.

Referring to FIG. 17, various electronic devices to which the display device 1 according to aspects is applied may include image display electronic devices, such as a smart phone 1000.1a, a tablet PC 1000.1b, a laptop 1000.1c, a TV 1000.1d, and a desk monitor 1000.1e, wearable electronic devices including display modules, such as smart glasses 1000.2a, a head mounted display 1000.2b, and a smart watch 1000.2c, and vehicle electronic devices 1000.3 including display modules, such as a dashboard of an automobile, center fascia, a center information display (CID) arranged on the dashboard, and a room mirror display.

According to one or more aspects, a display device and an electronic device with improved stability and optical characteristics may be provided. Further, a method of manufacturing the same may be provided.

However, the effects obtainable through the disclosure are not limited to the effects described above, and other technical effects not mentioned will be clearly understood by those skilled in the art from the description of the disclosure described below.

Each of the aspects described above may be implemented independently, but of course, the structure of each aspect may be applied in combination to other aspects.

As such, the disclosure has been described with reference to the aspects illustrated in the drawings, but is merely illustrative, and it will be understood by those skilled in the art that various modifications and variations of the aspects may be made.

The specific executions described in the aspects are merely illustrative, and do not limit the scope of the disclosure in any way. Furthermore, unless otherwise indicated obviously by terms, such as ʺessentialʺ, ʺimportantʺ, and the like, a component may not be a necessary component for the application of the disclosure.

In the specification, the use of the term “the” and similar referential terms may refer to both the singular and the plural. When a range is described in the aspects, it includes individual values within the range (unless otherwise indicated herein). This is the same as stating each individual value constituting the above range in the detailed description. Finally, operations constituting methods according to aspects may be performed in any suitable order unless otherwise indicated herein or otherwise clearly contradicted by context. These aspects are not necessarily limited by the order of description of operations. The use of any examples or illustrative terms in the aspect is merely to describe the aspect in detail, and the scope of the aspect is not limited by the examples or illustrative terms. Further, it will be understood by those skilled in the art that various modifications, combinations, and changes may be made depending on design conditions and factors within the scope of the present disclosure.

What is claimed is:

1. A display device comprising:
a display panel comprising a display area and a peripheral area surrounding the display area;
a protective film layer arranged on the display panel;
an adhesive layer arranged between the protective film layer and the display panel; and
an anti-reflection layer arranged on the protective film layer,
wherein the display panel comprises a substrate, a pixel layer on the substrate, and a color filter layer on the pixel layer, and
a storage modulus of the adhesive layer is less than a storage modulus of the protective film layer.

2. The display device of claim 1, wherein
the protective film layer comprises at least a urethane-based material.

3. The display device of claim 1, wherein
the protective film layer has a thickness of 100 μm to 300 μm.

4. The display device of claim 1, wherein
the anti-reflection layer comprises an upper surface having a moth-eye shape, the upper surface comprising a plurality of cone structures spaced apart from one another.

5. The display device of claim 4, wherein
adjacent cone structures of the plurality of cone structures are spaced apart from one another by a distance of 0.25 μm to 0.35 μm.

6. The display device of claim 4, wherein
each of the plurality of cone structures has a height of 0.2 μm to 0.25 μm.

7. The display device of claim 1, wherein
the anti-reflection layer is arranged on an outermost layer, and
a polarizing layer is not arranged on the anti-reflection layer.

8. The display device of claim 1, wherein
the anti-reflection layer is arranged on an outermost layer, and
a window is not arranged on the anti-reflection layer.

9. A method of manufacturing a display device, the method comprising: forming a display panel;
forming an adhesive layer on the display panel;
forming a protective film layer on the adhesive layer; and
forming an anti-reflection layer on the protective film layer,
wherein forming the display panel comprises:
forming a substrate;
forming a pixel layer on the substrate; and
forming a color filter layer on the pixel layer, and
a storage modulus of the adhesive layer is less than a storage modulus of the protective film layer.

10. The method of claim 9, wherein
forming of the adhesive layer comprises:
applying an adhesive, which is a material of the adhesive layer; and
curing the adhesive.

11. The method of claim 10, wherein
forming of the protective film layer comprises:
applying a protective resin, which is a material of the protective film layer, onto the adhesive layer; and
curing the protective resin.

12. The method of claim 9, wherein
forming the protective film layer comprises forming the protective film layer to a thickness of 100 μm to 300 μm.

13. The method of claim 9, wherein
forming of the anti-reflection layer comprises:
applying an anti-reflection resin, which is a material of the anti-reflection layer, onto the protective film layer; and
curing the anti-reflection resin.

14. The method of claim 13, further comprising
between applying the anti-reflection resin and curing the anti-reflection resin, printing the anti-reflection resin to form a moth-eye shape comprising a plurality of cone structures spaced apart from one another.

15. The method of claim 14, wherein
printing the anti-reflection resin comprises printing adjacent cone structures of the plurality of cone structures to be spaced apart from one another by a distance of 0.25 μm to 0.35 μm.

16. The method of claim 14, wherein
printing the anti-reflection resin comprises printing each of the plurality of cone structures to a height of 0.2 μm to 0.25 μm.

17. The method of claim 9, wherein
forming the anti-reflection layer comprises forming the anti-reflection layer on an outermost layer, and
further comprising not forming a polarizing layer on the anti-reflection layer.

18. The method of claim 9, wherein
forming the anti-reflection layer comprises forming the anti-reflection layer on an outermost layer, and
further comprising not forming a window on the anti-reflection layer.

19. An electronic device comprising a display device,
the display device comprising:
a display panel comprising a display area and a peripheral area surrounding the display area;
a protective film layer arranged on the display panel;
an adhesive layer arranged between the protective film layer and the display panel; and
an anti-reflection layer arranged on the protective film layer, wherein
the display panel comprises a substrate, a pixel layer on the substrate, and a color filter layer on the pixel layer, and
a storage modulus of the adhesive layer is less than a storage modulus of the protective film layer.

20. The electronic device of claim 19, wherein
the anti-reflection layer is arranged on an outermost layer, and
neither a polarizing layer nor a window are arranged on the anti-reflection layer.
